(19) United States
(12) Patent Application Publication
(10) Pub. No.: US 2005/0045890 A1
(43) Pub. Date: Mar. 3, 2005

(54) Electro-optical device, method of manufacturing the same, and electronic apparatus

(75) Inventor: Yasuji Yamasaki, Chino-city (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/895,966

(22) Filed: Jul. 22, 2004

(30) Foreign Application Priority Data
Aug. 4, 2003 (JP) 2003-286207
Jun. 30, 2004 (JP) 2004-193511

(51) Int. Cl. H01L 29/04

(52) U.S. Cl. 257/72

(57) ABSTRACT

Aspects of the invention provide an electro-optical device that can include data lines that are a built-in light shielding film, scanning lines, TFTs having a semiconductor layer to which scanning signals are supplied by the scanning lines, pixel electrodes to which image signals are supplied by the data lines through the TFTs, storage capacitors arranged below the data lines, and an insulating film covering the storage capacitors. The data lines can be formed to avoid stepped portions on the surface of the insulating film caused by the height of the storage capacitors. Thus, it can be possible to improve the light shielding performance of the thin film transistors with respect to the semiconductor layer, to reduce or prevent the generation of light leakage current, and to display high-quality images without flicker.

### BACKGROUND OF THE INVENTION

1. Field of Invention

Aspects of the invention relate to an electro-optical device, such as an active-matrix-driving liquid crystal device, an electrophoresis device such as electronic paper, an electro-luminescent (EL) display device, and a device including an electron emission element, such as a field emission display and a surface-conduction electron-emitter display, and to a method for manufacturing the same. Further, the invention also relates to an electronic apparatus including the electro-optical device.

2. Description of Related Art

In a thin film transistor (TFT) active matrix driving electro-optical device of the related art, when incident light is radiated onto a channel region of a pixel switching TFT provided in each pixel, light leakage current is generated due to excitation by light to change the characteristics of the TFT. In particular, in an electro-optical device for a light valve of a projector, since the intensity of the incident light is high, it is important to shield the channel region of the TFT or a peripheral region of the channel region from the incident light. Thus, the channel region or the peripheral region thereof is shielded from the incident light by a light shielding film that defines an aperture region of each pixel provided on a counter substrate or a light shielding film that passes over the TFT on a TFT array substrate and that is made of a metal film, such as AL (aluminum). Since the latter light shielding film is formed as a part of a laminated structure comprised of a TFT, a data line, a scanning line, a pixel electrode, and a storage capacitor on a substrate, it may be referred to as a built-in light shielding film.

However, the related art light shielding technology can have the following problems. In particular, in the above-described electro-optical device, in the laminated structure, the built-in light shielding film is formed above the TFT such that the channel region and the peripheral region thereof can be shielded from the light incident from above the TFT by the built-in light shielding film. However, since it is more strongly requested to make the electro-optical device smaller and more precise, the structure of the electro-optical device becomes more complicated as noted by the multi-layered laminated structure. Thus, the surface of the built-in light shielding film may be concavo-convex. This is because a plurality of components, such as the storage capacitors, is formed under the built-in light shielding film (that is, under the built-in light shielding film in the laminated structure) in order to make the electro-optical device smaller and more precise. As a result, the built-in light shielding film is affected by the heights of the components. In other words, upper components on an interlayer insulating film formed between the components are affected by the heights. As a result, the surface of the built-in light shielding film is concavo-convex.

Further, when the surface of the built-in light shielding film becomes concavo-convex, the incident light is reflected by the surface of the built-in light shielding film in an unexpected direction. As a result, the incident light may be incident on the semiconductor layer of the TFT or the channel region that is a part of the TFT. In particular, when the end of the built-in light shielding film is low and the remaining portion (hereinafter, referred to as a non-end portion) excluding the end are high, the light reflected by the end or an edge of the non-end portion is likely to be incident on the TFT. This is because the TFTs are commonly arranged on the substrate in a matrix in plan view and the built-in light shielding film is arranged to define aperture regions as described above, so that when light is reflected by the above-described respective portions of the built-in light shielding film, the light may not be incident on the TFT positioned immediately under the corresponding portion, however, the light is likely to be incident on other TFTs adjacent to the TFT positioned immediately under the corresponding portion. The light is more likely to be incident on other TFTs adjacent to the TFT positioned immediately under the corresponding portion when an inclined portion exists between the end and the non-end portion.

### SUMMARY OF THE INVENTION

Aspects of the invention have been made to solve the above problems. It is an object of the invention to provide an electro-optical device and a method of manufacturing the same capable of improving the light shielding performance of a semiconductor layer of thin film transistors to prevent the generation of light leakage current, thereby displaying high quality images without flicker. It is another object of the invention to provide an electronic apparatus including such an electro-optical device.

A first electro-optical device according to the invention can include, above a substrate, data lines extending in a fixed direction and scanning lines extending in a direction intersecting the data lines, thin film transistors having a semiconductor layer to which scanning signals are supplied by the scanning lines, pixel electrodes to which image signals are supplied by the data lines through the thin film transistors, and a built-in light shielding film arranged on the semiconductor layer. The width of the built-in light shielding film is smaller than the width of at least one of a circuit element and wiring lines formed below the built-in light shielding film.

According to the first exemplary electro-optical device of the invention, image signals are supplied from the data lines to the pixel electrodes and the supply of the image signals from the data lines to the pixel electrodes is stopped in accordance with the switching on or off of thin film transistors whose switching is controlled by scanning signals. Thus, active matrix driving can be performed.

Also, according to the invention, built-in light shielding film can further be included above the semiconductor layer that constitute the thin film transistor. Thus, when the electro-optical device is used as a light valve of a liquid crystal projector, it is possible to prevent relatively intense light incident on the light valve from being incident on the semiconductor layer, in particular, the channel region. As a result, it is possible to prevent light leakage current from being generated in the semiconductor layer, and, when the electro-optical device displays images, it is possible to prevent flicker from being generated on images. From the foregoing, according to the invention, it is possible to improve the image quality.

According to the invention, in particular, the width of the built-in light shielding film is smaller than the width of at least one (hereinafter, referred to as a circuit element, etc.) of a circuit element and wiring lines formed below the built-in light shielding film. As a result, the following structure is realized. In other words, first, it is assumed that there exists a laminated structure in which a layer having a circuit element formed thereon exists, an interlayer insulating film exists on the layer, and a built-in light shielding film exists on the interlayer insulating film. Here, the interlayer insulating film is necessary in order to prevent the circuit element and the built-in light shielding film from being short-circuited. Next, in such a structure, any stepped portions caused by the height of the circuit element are unavoidably formed on the surface of the interlayer insulating film. The stepped portions are formed to correspond to a region in which the circuit element is formed and to correspond to the width of the circuit element such that the width of a space between the stepped portions almost corresponds to the width of the circuit element, etc.

In such an environment, the width of the built-in light shielding film according to the invention can be smaller than the width of the circuit element, that is, the width of space between the stepped portions. Thus, since the built-in light shielding film is formed on a plane between the stepped portions, the surface of the built-in light shielding film is planarized and concavo-convex portions are not generated in the surface of the built-in light shielding film.

As described above, according to the invention, it is possible to prevent any concavo-convex portions from being generated on the surface of the built-in light shielding film, to prevent the light reflected by the surface of the built-in light shielding film from traveling in an unexpected direction, and to prevent the light from being incident on the semiconductor layer of the thin film transistor or on the channel region that is a part of the thin film transistor. Thus, according to the invention, it can be possible to reduce or prevent light leakage current from being generated in the semiconductor layer and to display high quality images.

Also, according to the invention, in order to improve the above-described effects, it is preferable that the entire built-in light shielding film be placed on the plane between the stepped portions of the interlayer insulating film. However, since it is difficult to realize such a structure in some cases, it is not strictly requested to realize such a structure.

According to the above-described structure, the built-in light shielding film is formed on the plane between the stepped portions. However, in some cases, any concavo-convex portions may exist between the stepped portions. In such a case, concavo-convex portions corresponding to the above-described concavo-convex portions are formed on the surface of the built-in light shielding film. However, it is not likely that the light reflected by the built-in light shielding film travel in an unexpected direction as long as the concavo-convex portions are not formed around the edge of the built-in light shielding film. Thus, in such a case, it is possible to obtain the above-described effects.

There is provided a second electro-optical device according to the invention includes, above a substrate, data lines extending in a fixed direction and scanning lines extending in a direction intersecting the data lines, thin film transistors having a semiconductor layer to which scanning signals are supplied by the scanning lines, pixel electrodes to which image signals are supplied by the data lines through the thin film transistors, a built-in light shielding film arranged on the semiconductor layer, at least one of a circuit element and wiring lines arranged below the built-in light shielding film, and an insulating film formed to cover at least one of a circuit element and wiring lines. The built-in light shielding film is formed to avoid stepped portions on the surface of the insulating film, which are formed by the height of at least one of a circuit element and wiring lines.

In the second electro-optical device of the invention, as in the first electro-optical device, active matrix driving can be performed. Also, according to the invention, the built-in light shielding film is further included. As a result, it is possible to prevent light leakage current from being generated in the semiconductor layer and to improve the image quality.

According to the invention, in particular, the built-in light shielding film is formed to avoid stepped portions on the surface of the insulating film, which are caused by the height of the circuit element. Thus, any concavo-convex portions caused by the stepped portions are not generated in the built-in light shielding film. As described above, according to the invention, it is possible to obtain the above-described effects as in the first electro-optical device.

According to an aspect, as described above, the entire built-in light shielding film is preferably formed to completely avoid the stepped portions. However, since it is difficult to realize such a structure in some cases, according to the invention, it is not strictly requested to realize such a structure.

There can be provided a third exemplary electro-optical device according to the invention can include, above a substrate, data lines extending in a fixed direction and scanning lines extending in a direction intersecting the data lines, thin film transistors having a semiconductor layer to which scanning signals are supplied by the scanning lines, pixel electrodes to which image signals are supplied by the data lines through the thin film transistors, a built-in light shielding film arranged on the semiconductor layer, at least one of a circuit element and wiring lines formed below the built-in light shielding film, and an insulating film covering the at least one of the circuit element and the wiring lines and having different heights in a portion of the insulating film immediately on at least one of the circuit element and the wiring lines and in portions other than the portion of the insulating film immediately on the at least one of the circuit element and the wiring lines. The built-in light shielding film is formed to correspond to the portion of the insulating film immediately on the at least one of the circuit element and the wiring lines.

According to the exemplary third electro-optical device of the invention, as in the first electro-optical device, active matrix driving can be performed. Also, according to the invention, the built-in light shielding film can be further included. As a result, it is possible to prevent light leakage current from being generated in the semiconductor layer and to improve the image quality.

According to the invention, in particular, the built-in light shielding film can be formed to cover the circuit element such that an insulating film having concavo-convex portions is included immediately on the circuit element and in portions that are not positioned immediately on the circuit element and that the built-in light shielding film is arranged to correspond to the portion positioned immediately on the circuit element. Thus, according to the invention, it is possible to obtain the above-described effects as in the first electro-optical device.

According to an aspect of the first exemplary electro-optical device of the invention, the electro-optical device can further include a planarized insulating film, whose surface is planarized, on the light shielding film, and at least one of a planarized circuit element and planarized wiring lines arranged on the planarized insulating film. In a portion where the at least one of the planarized circuit element and the planarized wiring lines is formed to cover the built-in light shielding film and in a portion where the at least one of the planarized circuit element and the planarized wiring lines is formed not to cover the built-in light shielding film, in at least the latter portion, the width of the built-in light shielding film is smaller than the width of at least one of the circuit element and wiring lines.

According to this aspect, at least one (hereinafter, referred to as a planarized circuit element, etc.) of planarized circuit element and planarized wiring lines is formed above the built-in light shielding film. When the planarized circuit element is formed to cover the built-in light shielding film, the planarized circuit element may function as a light shielding film. Thus, in such a case, when the planarized circuit element is formed to cover the built-in light shielding film, according to the electro-optical device, a double light shielding structure comprised of the planarized circuit element and the built-in light shielding film. In such a case, it is not necessary to have the built-in light shielding film below the planarized circuit element affected by restriction for planarization (hereinafter, simply referred to as restriction on width). This is because the traveling of the light incident from the above is blocked by the planarized circuit element positioned above the built-in light shielding film (furthermore, since the planarized circuit element is flat, it is not likely that the light reflected by the planarized circuit element travel in an unexpected direction).

As described above, according to the aspect, between the portion in which the planarized circuit element is formed to cover the built-in light shielding film and the portion in which the planarized circuit element is not formed to cover the built-in light shielding film, when only the latter portion is affected by the above-described restriction on width, it is possible to obtain the same effects according to the invention and to realize freer layout of the portion that is not necessarily affected by the restriction on width. As a result, it possible to improve the degree of freedom of design.

According to the aspect, the restriction on the widths of the built-in light shielding film and the circuit element is considered as the restriction for planarization. However, the invention is not limited to the above. It is apparent that the above discussion is true of restriction in other points of view (that is, restriction for having the built-in light shielding film formed to avoid the stepped portions or restriction for having the built-in light shielding film formed to correspond to the portion immediately on the circuit element.

According to the aspect, the built-in light shielding film may be affected by the restriction for planarization in the portion where the planarized circuit element is formed to cover the built-in light shielding film. Even if the planarized circuit element having light shielding performance exists, light that is transmitted through the planarized circuit element may exist. As a result the built-in light shielding film intercepts the light that is transmitted through the planarized circuit element. Also, when the built-in light shielding film is affected by the restriction for planarization in the portion where the planarized circuit element is formed to cover the built-in light shielding film, since double planarized light shielding films exist. As a result, it is possible to improve the above-described effects.

According to another aspect of the first to third exemplary electro-optical devices, the built-in light shielding film functions as the data lines. According to this aspect, since the built-in light shielding film functions as the data lines, it is possible to simplify the structure of the electro-optical device compared with the case in which the built-in light shielding film and the data lines are separately formed on the substrate.

According to another aspect of the first to third electro-optical devices, at least one of the circuit element and wiring lines can include all or a part of the thin film transistors. According to this aspect, since the circuit elements include all or parts of the thin film transistors, the laminated structure on the substrate is comprised of a thin film transistor, an interlayer insulating film, and a built-in light shielding film in the order from the bottom. In this case, since the thin film transistor has a three-layered structure comprised of, for example, a semiconductor layer, a gate insulating film, and a gate electrode film, the height of the thin film transistor is relatively large. As a result, the stepped portions of the interlayer insulating film formed on the thin film transistor may be relatively large. However, according to the invention, as described above, even if such stepped portions are formed, concavo-convex portions are not formed on the surface of the built-in light shielding film. From this point of view, according to the aspect, it is possible to appropriately realize the laminated structure and to effectively improve the effects of the invention.

According to another aspect of the first to third electro-optical devices of the invention, storage capacitors that are connected to the thin film transistors and the pixel electrodes are further comprised and at least one of a circuit element and wiring lines functions as at least a part of the storage capacitors. According to this aspect, since the circuit element function as the storage capacitors, the laminated structure on the substrate can be made of a storage capacitor, an interlayer insulating film, and a built-in light shielding film in the order from the bottom. In this case, since the storage capacitor has a three-layered structure can include, for example, a pixel-electric-potential-side capacitor electrode, a dielectric film, and a fixed-electric-potential-side capacitor electrode, the height of the storage capacitor is relatively large. As a result, the stepped portions of the surface of the interlayer insulating film formed on the storage capacitor may be relatively large. However, according to the invention, as described above, even if such stepped portions are formed, concavo-convex portions are not formed on the surface of the built-in light shielding film. From this point of view, according to the invention, it is possible to appropriately realize the laminated structure and to more effectively improve the effects of the invention.

According to another aspect of the first to third exemplary electro-optical devices of the invention, storage capacitors that are connected to the thin film transistors and the pixel electrodes are further comprised and the built-in light shielding film functions as at least a part of the storage capacitors.

According to this aspect, since the built-in light shielding film functions as at least a part (that is, when a storage capacitor is comprised of a pixel-electric-potential-side capacitor electrode, an insulating film, and a fixed-electric-potential-side capacitor electrode, all or a part thereof) of the storage capacitor, it is possible to simplify the structure of the electro-optical device compared with the case in which the built-in light shielding film and the storage capacitor are separately formed on the substrate.

According to the exemplary electro-optical device of the invention, other than the built-in light shielding film that function as the storage capacitors according to the present aspect, a built-in light shielding film that functions as the data lines may be further comprised. In this case, according to the electro-optical device, two kinds of built-in light shielding films exist in the upper layer and in the lower layer of the laminated structure. Thus, it is possible to completely prevent light from being incident on the semiconductor layer.

According to another aspect of the first to third exemplary electro-optical devices of the invention, the pixel electrodes and the thin film transistors are arranged on the substrate in a matrix in plan view and the built-in light shielding films are arranged in a matrix excluding the regions in which the pixel electrodes are formed. According to this aspect, since the built-in light shielding film is arranged in a matrix, it is possible to increase the area of the built-in light shielding film. As a result, it is possible to reduce or completely prevent light from being incident on the semiconductor layer.

According to the aspect, since the thin film transistors are arranged in a matrix, when attention is paid to a certain thin film transistor, thin film transistors adjacent to the one thin film transistor exist. Then, stepped portions are generated at the edge of the built-in light shielding film. When the incident light is reflected by the surface of the built-in light shielding film positioned above the one thin film transistor, in particular, the surface around the stepped portions at the edge of the built-in light shielding film, the reflected light may be incident on the adjacent thin film transistors. However, according to the invention, since at least one of the restriction on the width of the built-in light shielding film and the circuit element, the restriction for having the built-in light shielding film avoid the stepped portions, and the restriction for having the built-in light shielding film correspond to the portion positioned immediately on the circuit element is applied, the concavo-convex portions are not formed at the edge of the built-in light shielding film. Thus, according to the present aspect, it is possible to prevent light from being incident on the adjacent thin film transistors.

The built-in light shielding film is formed to exclude the region in which the pixel electrodes are formed means that the built-in light shielding film and the pixel electrodes overlap each other (for example, the edge of the built-in light shielding film and the edge of the pixel electrodes overlap each other in plan view) as well as the built-in light shielding film is formed in the region completely excluding the regions in which the pixel electrodes are formed.

That the built-in light shielding films are arranged in a matrix means that the built-in light shielding film is arranged throughout the entire matrix in which the built-in light shielding film is integrally arranged in a matrix to be continuous or the built-in light shielding films are separated from each other. As a specific example of the latter, the built-in light shielding film is formed of built-in light shielding films in stripes and bridging built-in light shielding films arranged to bridge the built-in light shielding films in stripes though not connected to the built-in light shielding films in stripes. In this case, the pattern inside the bridging built-in light shielding films are further divided to form first, second, . . . , and nth bridging built-in light shielding films.

Furthermore, such bridging built-in light shielding films may be used as relay layers (refer to a capacitor wiring line relay layer 6a1 and a second relay electrode 6a2 according to an embodiment of the invention which will be described below) for electrically connecting the circuit element and the wiring lines in the lower layer to the circuit element and the wiring lines in the upper layer. Thus, it is possible to miniaturize the electro-optical device and to appropriately realize the laminated structure on the substrate.

According to another aspect of the first to third exemplary electro-optical devices of the invention, the built-in light shielding film has a multi-layered structure. According to this aspect, since the built-in light shielding film has one layer made of a material having good light absorbing performance and another layer made of a material having good light reflecting performance, it is possible to improve the performance of the built-in light shielding film as a light shielding film. According to this aspect, the multi-layered structure may include a layer made of titan nitride and a layer made of aluminum. According to such a structure, since the layer made of titan nitride has relatively good light absorbing performance and the layer made of aluminum has relatively good light reflecting performance, it is possible to improve the light shielding performance of the built-in light shielding film.

A method of manufacturing an electro-optical device can include a step of forming at least one of a circuit element and wiring lines above a substrate, step of forming an insulating film on at least one of the circuit element and wiring lines, a step of forming a built-in light-shielding-film precursor film on the insulating film, and a step of patterning the built-in light-shielding-film precursor film so as to leave a portion of the built-in light-shielding-film precursor film, which is formed to correspond a portion of the insulating film immediately on the at least one of the circuit element and wiring lines, thereby forming a built-in light shielding film.

According to the method of manufacturing the electro-optical device according to the invention, it is possible to appropriately manufacture the above-described third electro-optical device according to the invention. The built-in light-shielding-film precursor film is formed immediately on at least one of a circuit element and wiring lines means that the width of the built-in light shielding film is smaller than the width of at least one of the circuit element and wiring lines according to the above-described first electro-optical device of the invention and that the built-in light shielding film is formed to avoid the stepped portion on the surface of the insulating film, which is formed by the height of at least one of the circuit element and wiring lines according to the above-described second electro-optical device of the invention. Thus, according to the method of manufacturing the electro-optical device of the invention, it is possible to appropriately manufacture the above-described first to third electro-optical devices of the invention.

The electronic apparatus according to the invention can include the above-described first to third exemplary electro-optical devices of the invention (including various aspects) in order to solve the problems.

Since the electronic apparatus of the invention can include the above-described electro-optical device according to the invention, it is possible to realize various electronic apparatuses, such as a projection type display device, a liquid crystal TV, a mobile telephone, an electronic organizer, a word processor, a view finder type or monitor direct view type video tape recorder, a workstation, a picture telephone, a POS terminal, and a touch panel, capable of displaying high quality images without flicker.

### BRIEF DESCRIPTION OF THE DRAWINGS

The invention will be described with reference to the accompanying drawings, wherein like numerals reference like elements, and wherein:

FIG. 1 is an equivalent circuit of various elements and wiring lines in a plurality of pixels that are formed in a matrix and that constitute an image display region of an electro-optical device;

FIG. 2 is a plan view of a group of a plurality of pixels adjacent to each other of a TFT array substrate on which data lines, scanning lines, and pixel electrodes are formed, which illustrates only components related to a lower layer portion (a lower layer portion to the storage capacitor 70 in FIG. 4);

FIG. 3 is a plan view of the group of plurality of pixels adjacent to each other of the TFT array substrate on which the data lines, the scanning lines, and the pixel electrodes are formed, which illustrates only components related to an upper layer portion (an upper layer portion over the storage capacitor 70 in FIG. 4);

FIG. 4 is a sectional view taken along the line A-A′ when FIGS. 2 and 3 overlap each other;

FIG. 5 is a sectional view taken along the line B-B′ when FIGS. 2 and 3 overlap each other;

FIG. 6 is a comparative example of FIG. 5;

FIG. 7 is a sectional view of the manufacturing processes of the data lines as seen from the viewing location of FIG. 5;

FIG. 8 is a sectional view taken along the line C-C′ when FIGS. 2 and 3 overlap each other;

FIG. 9 is a sectional view taken along the line D-D′ when FIGS. 2 and 3 overlap each other;

FIG. 10 is a sectional view similar to FIG. 5, which illustrates a structure in which capacitor wiring lines 400 and a fourth interlayer insulating film 44 of FIG. 5 do not exist;

FIG. 11 is a sectional view similar to FIG. 8, which illustrates a structure in which the storage capacitor 70 of FIG. 8 is formed in a different way;

FIG. 12 is a sectional view similar to FIG. 9, which illustrates a structure in which the storage capacitor 70 and the relay electrode 719 of FIG. 9 are formed in a different way;

FIG. 13 is a plan view of the electro-optical device as the TFT array substrate is seen from the side of a counter substrate together with the components formed thereon;

FIG. 14 is a sectional view taken along the line H-H′ of FIG. 13;

FIG. 15 is a schematic sectional view illustrating a color liquid crystal projector that is an example of a projection type color display apparatus that is an embodiment of an electronic apparatus according to the invention; and

FIG. 16 is a view illustrating an example of the planar arrangement of a built-in light shielding film 6a and the storage capacitor 70 of FIG. 10.

### DETAILED DESCRIPTION OF PREFERRED EMBODIMENTS

An exemplary embodiment of the invention will now be described with reference to the drawings. According to the embodiment, an electro-optical device according to the invention is applied to a liquid crystal device.

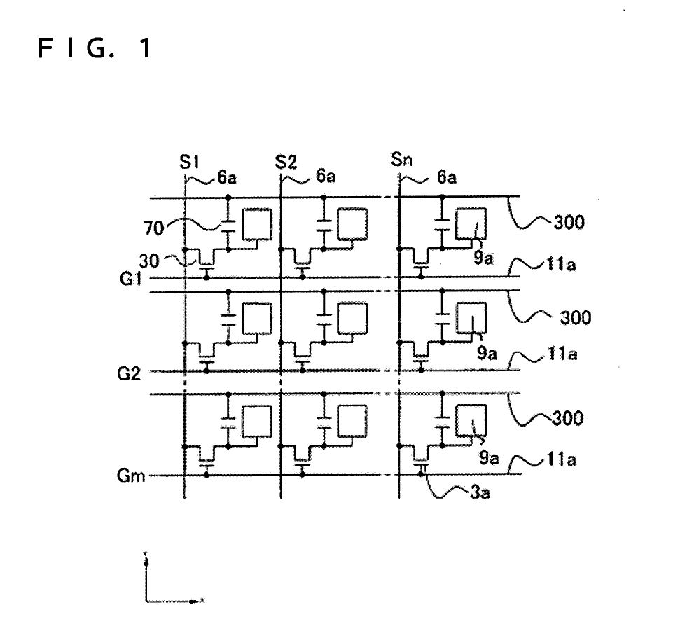

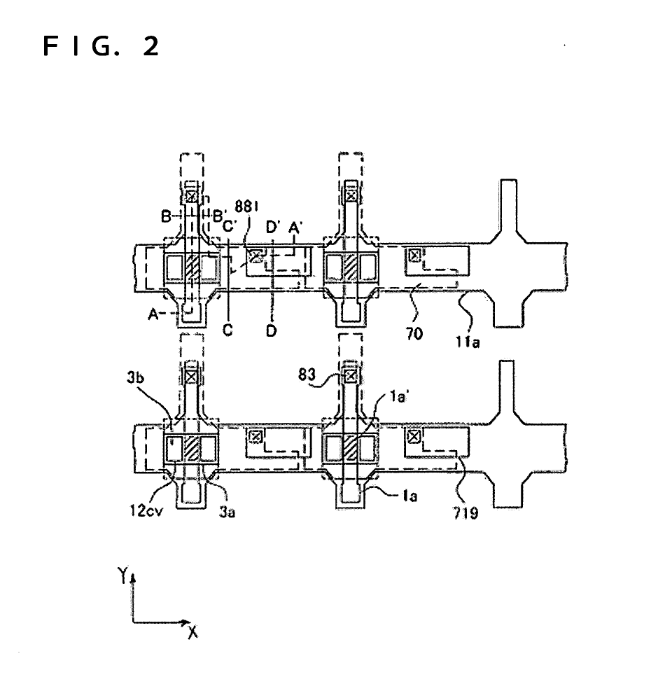

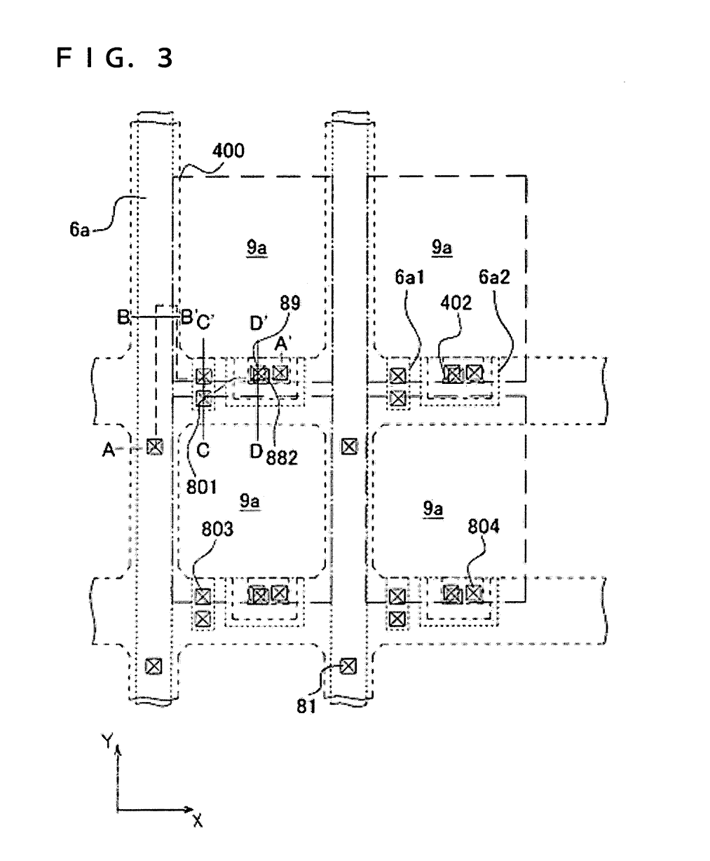

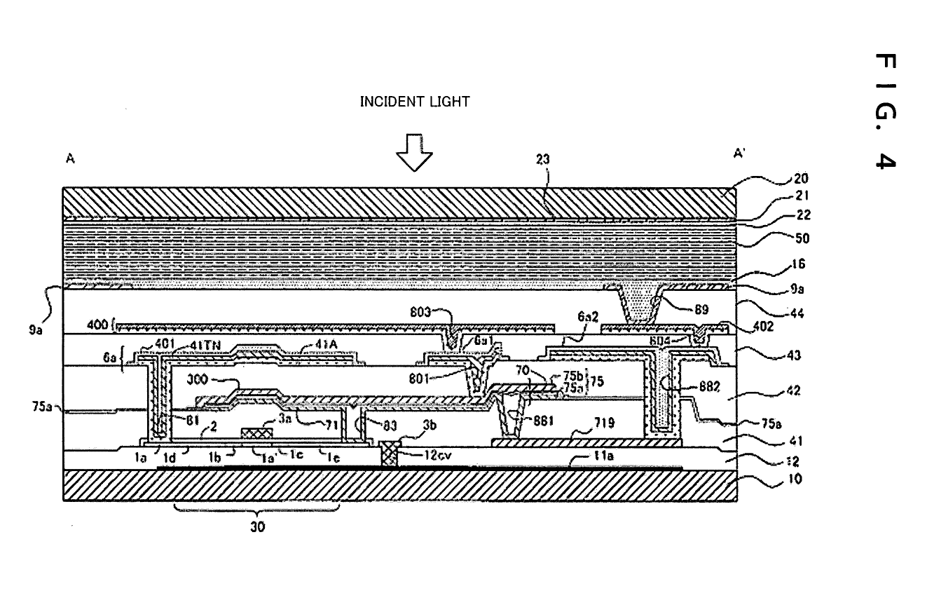

The structure of a pixel portion of an electro-optical device according to an exemplary embodiment of the invention will now be described with reference to FIGS. 1 to 4. Here, FIG. 1 is an equivalent circuit of various elements, wiring lines, etc. in a plurality of pixels that is formed in a matrix and that constitutes an image display region of the electro-optical device. FIGS. 2 and 3 are plan views of a group of a plurality of pixels adjacent to each other on a TFT array substrate on which data lines, scanning lines, and pixel electrodes are formed. Also, FIGS. 2 and 3 respectively illustrate a lower layer (FIG. 2) and an upper layer (FIG. 3) in a laminated structure to be described later. FIG. 4 is a sectional view taken along the line A-A′ when FIGS. 2 and 3 overlap. In FIG. 4, the contraction scales of each layer and member are different to make each layer and member recognizable in the figure.

Hereinafter, after describing the basic structure of the electro-optical device according to the exemplary embodiment, the characteristic structure of the present embodiment will be described in detail below.

In FIG. 1, pixel electrodes 9a and TFTs 30 for controlling switching of the pixel electrodes 9a are formed in a plurality of pixels that is formed in a matrix and that constitutes an image display region of an electro-optical device according to the present embodiment. Data lines 6a to which image signals are supplied are electrically connected to the sources of the TFTs 30. The image signals S1, S2, . . . , and Sn written in the data lines 6a may be line-sequentially supplied in this order and may be supplied to respective groups each being comprised of a plurality of adjacent data lines 6a.

Gate electrodes 3a are electrically connected to the gates of the TFTs 30. At a predetermined timing, scanning signals G1, G2, . . . , and Gm are line-sequentially applied to scanning lines 11a and the gate electrodes 3a in pulses in this order. The pixel electrodes 9a are electrically connected to the drains of the TFTs 30, and the switches of the TFTs 30, which are switching elements, are closed for a certain period of time, such that the image signals S1, S2, . . . , and Sn supplied from the data lines 6a are written at a predetermined timing.

A predetermined level of the image signals S1, S2, . . . , and Sn that are written in liquid crystal, an example of an electro-optical material, through the pixel electrodes 9a are stored between the corresponding pixel electrode and a counter electrode formed on a counter substrate for a certain period of time. The alignment or order of the molecules of the liquid crystal changes according to the level of an applied voltage, such that light is modulated to allow grayshade. In a normally white mode, the transmittance of incident light decreases in accordance with a voltage applied to each pixel. In a normally black mode, the transmittance of the incident light increases in accordance with a voltage applied to each pixel. Thus, light having contrast in accordance with the image signals is emitted from the electro-optical device.

Here, in order to prevent the stored image signals from leaking, storage capacitors 70 are added in parallel to liquid crystal capacitors formed between the pixel electrodes 9a and the counter electrode. The storage capacitors 70 are juxtaposed to the scanning lines 11a and include fixed-electric-potential-side capacitor electrodes and the capacitor electrodes 300 fixed to the electrostatic potential.

The specific structure of the electro-optical device in which the above-described circuit operation is realized by the data lines 6a, the scanning lines 11a, the gate electrodes 3a, and the TFTs 30 will now be described with reference to FIGS. 2 to 4.

First, in FIG. 3, the plurality of pixel electrodes 9a are provided on a TFT array substrate 10 in a matrix (the contours are marked with dotted lines) and the data lines 6a and the scanning lines 11a are provided along the vertical and horizontal boundaries of the pixel electrodes 9a. The data lines 6a have a laminated structure including aluminum, to be described later. The scanning lines 11a are made of, for example, a conductive poly-silicon film, etc. The scanning lines 11a are electrically connected to the gate electrodes 3a that face channel regions 1a′ in the regions marked with upward-leaning oblique lines in a semiconductor layer 1a through contact holes 12cv. The gate electrodes 3a are included in the scanning lines 11a. That is, in the portions of the channel region 1a′ where the gate electrodes 3a intersect the data lines 6a, the pixel switching TFTs 30 opposite to which the gate electrodes 3a included in the scanning lines 11a are disposed are provided. Thus, the TFTs 30 (excluding the gate electrodes 3a) are positioned between the gate electrodes 3a and the scanning lines 11a.

Next, as illustrated in FIG. 4, which is a sectional view taken along the line A-A′ of FIGS. 2 and 3, the electro-optical device comprises a TFT array substrate 10 made of a quartz substrate, a glass substrate, a silicon substrate, etc., and a counter substrate 20 made of a glass substrate or a quartz substrate, which faces the TFT array substrate 10.

On the side of the TFT array substrate 10, as illustrated in FIG. 4, the pixel electrodes 9a are provided. An alignment film 16 that has been predetermined aligning, such as rubbing, is performed, is provided on the pixel electrodes 9a. The pixel electrodes 9a are made of, for example, a transparent conductive film, such as an indium tin oxide (ITO) film. On the other hand, on the side of the counter substrate 20, a counter electrode 21 is provided over the entire surface. An alignment film 22 that has been subjected to predetermined aligning, such as rubbing, is provided under the counter electrode 21. The counter electrode 21 is made of a transparent conductive film, such as an ITO film, similar to the above-described pixel electrodes 9a.

An electro-optical material, such as liquid crystal, is filled in a space surrounded by a sealing material 52 (refer to FIGS. 17 and 18), to be described later, between the TFT array substrate 10 and the counter substrate 20 that face each other, to form a liquid crystal layer 50. The liquid crystal layer 50 is given a predetermined alignment state by the alignment films 16 and 22 when an electric field is not applied from the pixel electrodes 9a.

On the other hand, on the TFT array substrate 10, various components including the pixel electrodes 9a and the alignment film 16 form a laminated structure. As illustrated in FIG. 4, the laminated structure is comprised of a first layer including the scanning lines 11a, a second layer including the TFTs 30 that include the gate electrodes 3a, a third layer including the storage capacitors 70, a fourth layer including data lines 6a, a fifth layer including capacitor wiring lines 40, and a sixth layer (the uppermost layer) including the pixel electrodes 9a and the alignment film 16, in the order from the bottom. An underlying insulating film 12 is provided between the first layer and the second layer. A first interlayer insulating film 41 is provided between the second layer and the third layer. A second interlayer insulating film 42 is provided between the third layer and the fourth layer. A third interlayer insulating film 43 is provided between the fourth layer and the fifth layer. A fourth interlayer insulating film 44 is provided between the fifth layer and the sixth layer. Thus, it is possible to prevent the above-described components from being short-circuited. Contact holes for electrically connecting highly doped source regions id in the semiconductor layer 1a of the TFTs 30 to the data lines 6a are provided in the respective insulating films 12, 41, 42, 43, and 44. The respective components will now be sequentially described from the bottom. Among the above-described layers, from the first layer to the third layer is illustrated in FIG. 2 as a lower layer. From the fourth layer to the sixth layer is illustrated in FIG. 3 as an upper layer.

First, scanning lines 11a are provided in the first layer. The scanning lines 11a are made of elemental metal, an alloy, metal silicide, poly-silicide including at least one of high-melting-point metal, such as Ti, Cr, W, Ta, and Mo, and laminates thereof, or conductive poly-silicon. The scanning lines 11a are patterned in stripes in plan view in the X-direction of FIG. 2. More specifically, the scanning lines 11a in stripes include main line portions that extend in the X-direction of FIG. 2, and protruding portions that extend in the Y-direction of FIG. 2 to which the data lines 6a or the capacitor wiring lines 400 extend. The protruding portions that extend from the adjacent scanning lines 11a are not connected to each other. Thus, each of the scanning lines 11a is isolated.

Next, the TFTs 30 including the gate electrodes 3a are provided as the second layer. As illustrated in FIG. 4, the TFTs 30 have a lightly doped drain (LDD) structure and include the above-described gate electrodes 3a, the channel regions 1a′ of the semiconductor layer 1a, which are made of a poly-silicon film and which have channels formed by the electric field from the gate electrodes 3a, insulating films 2 including a gate insulating film for insulating the gate electrodes 3a from the semiconductor layer 1a, and lightly doped source regions 1b, lightly doped drain regions 1c, highly doped source regions 1d, and highly doped drain regions 1e in the semiconductor layer 1a.

According to the exemplary embodiment, relay electrodes 719 are formed on the second layer using the same film as the gate electrodes 3a. As illustrated in FIG. 2, each of the relay electrodes 719 is formed in the shape of an island in plan view, to be positioned substantially in the center of a side that extends in the X-direction of each of the pixel electrodes 9a. Since the relay electrodes 719 and the gate electrodes 3a are made of the same film, for example, when the gate electrodes 3a are made of the conductive poly-silicon film, the relay electrodes 719 are also made of the conductive poly-silicon film.

As illustrated in FIG. 4, the above-described TFTs 30 preferably have the LDD structure: however, they may have an offset structure in which impurities are not implanted into the lightly doped source regions 1b and the lightly doped drain regions 1c. Self-aligned-type TFTs having highly doped source regions and highly doped drain regions formed by self-matching by implanting impurities in high concentration using the gate electrodes 3a as a mask may be used.

The underlying insulating film 12 can be made of a silicon oxide film, etc., is provided on the scanning lines 11a and under the TFTs 30. The underlying insulating film 12 interlayer-insulates the TFTs 30 from the scanning lines 11a. Also, the underlying insulating film 12 formed on the entire surface of the TFT array substrate 10 prevents the characteristics of the pixel switching TFTs 30 from changing due to the roughness caused by the process of abrading the surface of the TFT array substrate 10, and the dirt that remains after cleaning the TFT array substrate 10.

Contact holes 12cv are formed in the underlying insulating film 12 at both sides of the semiconductor layer 1a, in plan view, in the direction of the channel length of the semiconductor layer 1a that extends along the data lines 6a, to be described later. Corresponding to the contact holes 12cv, concave portions are formed under the gate electrodes 3a laminated above the contact holes 12cv. The gate electrodes 3a are formed to cover the entire region of the contact holes 12cv, such that sidewall portions 3b (the above-described concave portions) integrally formed with the gate electrodes 3a are provided in the gate electrodes 3a. Thus, as illustrated in FIG. 2, the semiconductor layer 1a of the TFTs 30 are covered from the side in plan view, which makes it possible to prevent light from being incident on the covered portions.

The sidewall portions 3b are formed to bury the contact holes 12cv, and the lower ends thereof are connected to the scanning lines 11a. Here, the scanning lines 11a are formed in stripes, as described above, such that the gate electrode 3a and the scanning line 11a in a certain row always have the same electric potential in the row.

In the third layer next to the above-described second layer, the storage capacitors 70 can be provided. The storage capacitors 70 are formed such that lower electrodes 71, serving as pixel-electric-potential-side capacitor electrodes and being connected to the highly doped drain regions 1e of the TFTs 30 and the pixel electrodes 9a, face the capacitor electrodes 300, serving as fixed-electric-potential-side capacitor electrodes, with dielectric films 75 interposed therebetween. According to the storage capacitors 70, it is possible to significantly improve the potential storage characteristics of the pixel electrodes 9a. As illustrated in FIG. 2, the storage capacitors 70 according to the present embodiment do not reach light transmission regions almost corresponding to the regions in which the pixel electrodes 9a are formed. That is, since the storage capacitors 70 are accommodated in light shielding regions, the pixel aperture ratio of the entire electro-optical device remains large, which makes it possible to display brighter images.

More specifically, the lower electrodes 71 are made of a conductive poly silicon film and function as the pixel-electric-potential-side capacitor electrodes. The lower electrodes 71 may be formed of a single layered film or a multi-layered film including metal or an alloy. The lower electrodes 71 have a function of relay connecting the pixel electrodes 9a to the highly doped drain regions 1e of the TFTs 30 as well as the functions of the pixel-electric-potential-side capacitor electrodes. Furthermore, the relay connection described herein is performed through the relay electrodes 719.

The capacitor electrodes 300 function as the fixed-electric-potential-side capacitor electrodes of the storage capacitors 70. According to the exemplary embodiment, in order to make the capacitor electrodes 300 have the fixed electric potential, the capacitor electrodes 300 must be electrically connected to the capacitor wiring lines 400 (which will be described later) having the fixed electric potential. The capacitor electrodes 300 are made of elemental metal, an alloy, metal silicide, poly-silicide, including at least one of high-melting-point metals, such as Ti, Cr, W, Ta, and Mo and laminates thereof, or preferably, tungsten silicide. Thus, the capacitor electrodes 300 prevent light from being incident on the TFTs 30 from the above.

The dielectric films 75 are made of a relatively thin silicon oxide film having a thickness of about 5 to 200 nm, such as a high temperature oxide (HTO) film and a low temperature oxide (LTO) film or a silicon nitride film. In order to increase the capacitance of the storage capacitors 70, the dielectric films 75 are preferably thinner as long as it is possible to obtain sufficient reliability.

According to the exemplary embodiment, as illustrated in FIG. 4, the dielectric films 75 have a two-layered structure comprised of, for example, the silicon oxide film 75a in the lower layer and the silicon nitride film 75b in the upper layer. The silicon nitride film 75b in the upper layer is patterned to be slightly larger than the lower electrodes 71 of the pixel-electric-potential-side capacitor electrodes and to enter a light shielding region (a non-aperture region).

According to the exemplary embodiment, the dielectric films 75 have a two-layered structure. However, in some cases, the dielectric films 75 may have a three-layered structure comprised of, for example, a silicon oxide film, a silicon nitride film, and a silicon oxide film or a laminated structure of three or more layers. Also, the dielectric films 75 may have a single-layered structure.

A first interlayer insulating film 41 made of a silicate glass film, such as NSG (Non Silicate Glass), PSG (Phosphorus Silicate Glass), BSG (Boron Silicate Glass), BPSG (Boron Phosphorus Silicate Glass), etc., a silicon nitride film, or a silicon oxide film, or preferably NSG, is formed on the TFTs 30 or the gate electrodes 3a, on the relay electrodes 719, and under the storage capacitors 70.

In the first interlayer insulating film 41, contact holes 81 for electrically connecting the highly doped source regions id of the TFTs 30 to the data lines 6a, to be described later, are provided to pass through the second interlayer insulating film 42, to be described later. Also, in the first interlayer insulating film 41, contact holes 83 for electrically connecting the highly doped drain regions 1e of the TFTs 30 to the lower electrodes 71 that constitute the storage capacitors 70 are formed. Furthermore, in the first interlayer insulating film 41, contact holes 881 for electrically connecting the lower electrodes 71, serving as the pixel-electric-potential-side capacitor electrodes that constitute the storage capacitors 70, to the relay electrodes 719 are provided. Furthermore, in the first interlayer insulating film 41, contact holes 882 for electrically connecting the relay electrodes 719 to the second relay electrodes 6a2, to be described below, are formed to pass through the second interlayer insulating film, to be described later.

In the fourth layer next to the third layer, the data lines 6a are provided. As illustrated in FIG. 4, the data lines 6a have a three-layered structure comprised of, for example, a layer made of aluminum (refer to the reference numeral 41A in FIG. 4), a layer made of titanium nitride (refer to the reference numeral 41TN in FIG. 4), and a layer made of silicon nitride (refer to the reference numeral 401 in FIG. 4) in the order from the bottom. The silicon nitride film is patterned with a little large size to cover the aluminum layer and the titan nitride layer thereunder.

Also, in the fourth layer, capacitor wiring line relay layer 6a1 and the second relay electrode 6a2 are formed of the same film as the data lines 6a. As illustrated in FIG. 3, they are not continuous to the data lines 6a on a plane but are isolated from each other after being patterned in plan view. For example, when attention is paid to the data line 6a positioned on the leftmost side in FIG. 3, the substantially quadrangular capacitor wiring line relay layer 6a1 and the substantially quadrangular second relay electrode 6a2 whose area is slightly larger than that of the capacitor wiring line relay layer 6a1 are formed on the right side of the data line 6a.

In addition, since the capacitor wiring line relay layer 6a1 and the second relay electrode 6a2 are formed of the same film as the data lines 6a, they have a three-layered structure having, for example, the layer made of aluminum, the layer made of titan nitride, and the layer made of plasma nitride film, in the order from the bottom.

The second interlayer insulating film 42 formed of the silicate glass film, such as NSG, PSG, BSG, and BPSG, the silicon nitride film or the silicon oxide film, or preferably formed by a chemical vapor deposition (CVD) method using TEOS gas is provided on the storage capacitors 70 and under the data lines 6a. In the second interlayer insulating film 42, the contact holes 81 for electrically connecting the highly doped source regions Id of the TFTs 30 to the data lines 6a and contact holes 801 for electrically connecting the capacitor wiring line relay layer 6a1 to capacitor electrodes 300 that are the upper electrodes of the storage capacitors 70 are provided. Furthermore, in the second interlayer insulating film 42, the contact holes 882 for electrically connecting the second relay electrodes 6a2 to the relay electrodes 719, are formed.

In the fifth layer next to the fourth layer, capacitor wiring lines 400 are formed. As illustrated in FIG. 3, the capacitor wiring lines 400 are formed in a matrix to extend in the X and Y-directions in the drawing in plan view. The portions of the capacitor wiring lines 400 that extend in the Y-direction in the drawing are wider than the data lines 6a in order to cover, particularly, the data lines 6a. Also, each of the portions of the capacitor wiring lines 400 that extend in the direction X in the drawing has a cutout in the center of one side of each of the pixel electrodes 9a in order to secure regions in which the third relay electrodes 402 are formed.

In FIG. 3, at the corners of the intersections of the capacitor wiring lines 400 that extend in the X and Y-directions, substantially triangular portions are provided to cover the corners. Since the substantially triangular portions are provided in the capacitor wiring lines 400, it is possible to effectively shield the semiconductor layer 1a of the TFTs 30 from light. In other words, the light that would otherwise be incident on the semiconductor layer 1a from the upper side in an inclined direction is reflected by or absorbed into the triangular portions, such that the light does not reach the semiconductor layer 1a. Thus, it is possible to prevent light leakage current from being generated, thus displaying high quality images without flicker. The capacitor wiring lines 400 extend from the image display region 10a in which the pixel electrodes 9a are arranged to the vicinity thereof to be electrically connected to an electrostatic potential source and to have fixed electric potential.

In the fourth layer, the third relay electrodes 402 are formed of the same film as the capacitor wiring lines 400. The third relay electrodes 402 relay electrical connection between the second relay electrodes 6a2 and the pixel electrodes 9a through contact holes 804 and 89, to be described later. The capacitor wiring lines 400 and the third relay electrodes 402 are not continuous with each other on a plane but are isolated from each other after being patterned.

On the other hand, the capacitor wiring lines 400 and the third relay electrodes 402 have a two-layered structure comprised of, for example, the layer made of aluminum as a lower layer and the layer made of titanium nitride as an upper layer.

The third interlayer insulating film 43 made of a silicate glass film, such as NSG, PSG, BSG, and BPSG, a silicon nitride film, or a silicon oxide film, and preferably formed by a CVD method using TEOS gas is formed on the data lines 6a and under the capacitor wiring lines 400. In the third interlayer insulating film 43, contact holes 803 for electrically connecting the capacitor wiring lines 400 to the capacitor wiring line relay layer 6a1 and contact holes 804 for electrically connecting the third relay electrodes 402 to the second relay electrodes 6a2 are formed.

Finally, in the sixth layer, as described above, the pixel electrodes 9a are formed in a matrix. The alignment film 16 is formed on the pixel electrodes 9a. The fourth interlayer insulating film 44 made of the silicate glass film, such as NSG, PSG, BSG, and BPSG, the silicon nitride film, or the silicon oxide film, or preferably, of NSG is formed under the pixel electrodes 9a. In the fourth interlayer insulating film 44, contact holes 89 for electrically connecting the pixel electrodes 9a to the third relay electrodes 402, are formed. The pixel electrodes 9a and the TFTs 30 are electrically connected to each other through the contact holes 89, the third relay layer 402, the contact holes 804, the second relay layer 6a2, the contact holes 882, the relay electrodes 719, the contact holes 881, the lower electrodes 71, and the contact holes 83.

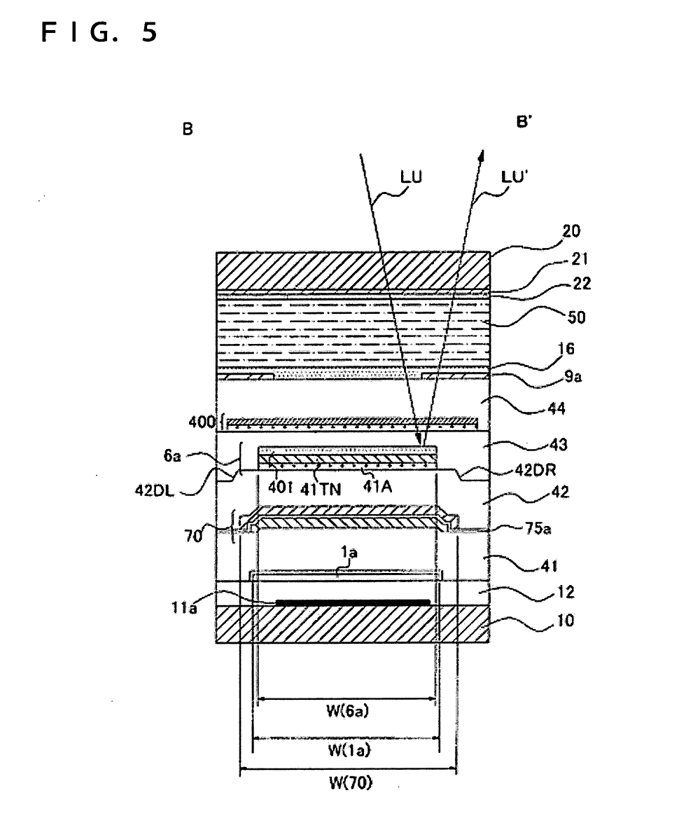

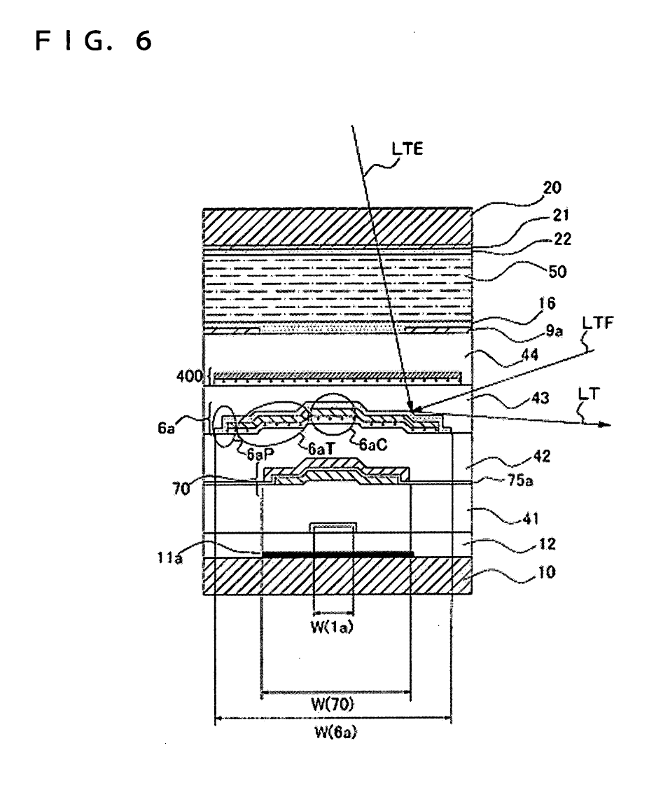

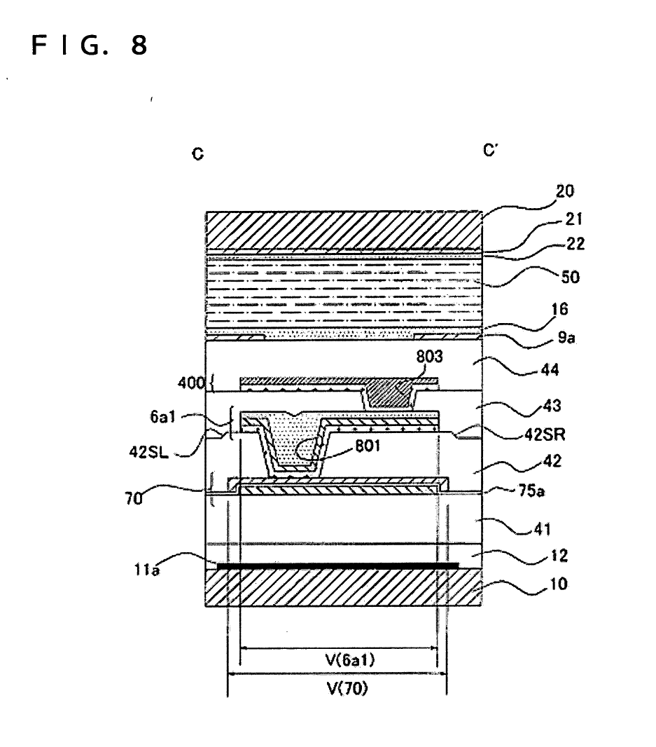

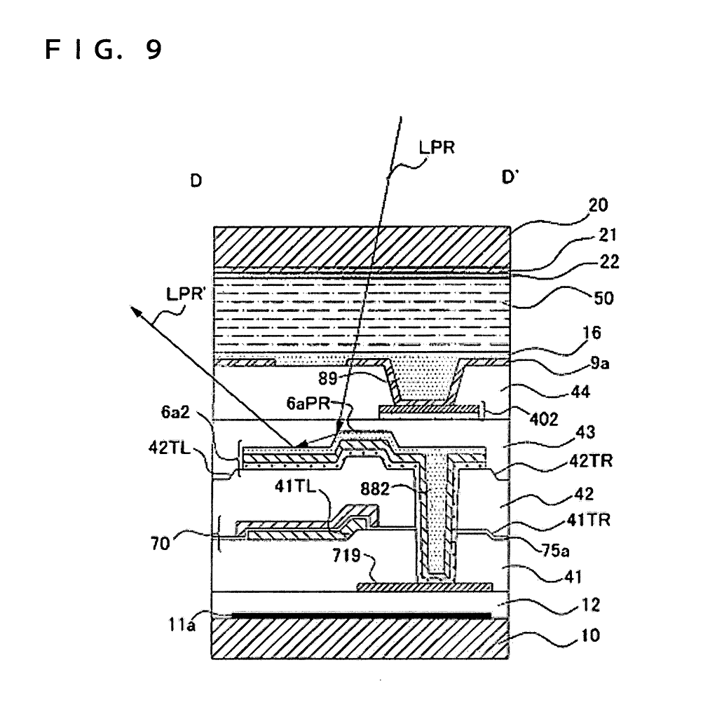

In the electro-optical device having the above-described structure, according to the exemplary embodiment, the relationship between the data lines 6a and the capacitor wiring lines 400 that are the built-in light shielding films and the components formed under the data lines 6a and the capacitor wiring lines 400, in particular, the storage capacitors 70 is characterized as follows, which will be described in detail with reference to FIGS. 5, 6, 8, and 9. FIG. 5 is a sectional view taken along the line B-B′ when FIGS. 2 and 3 overlap each other. FIG. 6 is a comparative example of FIG. 5. FIGS. 8 and 9 are a sectional view taken along the line C-C′ and a sectional view taken along the line D-D′ when FIGS. 2 and 3 overlap each other, respectively. In FIGS. 5 to 9, the contraction scales of each layer and member are different to make each layer and member recognizable in the figure.

FIG. 5 is a sectional view taken along the line B-B′ of FIGS. 2 and 3. The structure of the corresponding section is the same as the above-mentioned structure of FIG. 4. That is, in FIG. 5, a laminated structure having, for example, the scanning lines 1a, the underlying insulating film 12, the TFTs 30 including the semiconductor layer 1a, the first interlayer insulating film 41, the storage capacitors 70, the second interlayer insulating film 42, and the data lines 6a is realized in the order from the TFT array substrate 10. Among the above components, the data lines 6a are made of a film having the three-layered structure having, for example, the layer (refer to the reference numeral 41A in FIG. 5) made of aluminum, the layer (refer to the reference numeral 41TN in FIG. 5) made of titanium nitride, and the layer (refer to the reference numeral 401 in FIG. 5) made of silicon nitride in the order from the bottom as described above. Among them, in particular, aluminum is a material having good light reflecting performance and the film made of titanium nitride is a material having good light absorbing performance. On the other hand, the capacitor wiring lines 400 have the two-layered structure comprised of, for example, the layer made of aluminum in the lower layer and the layer made of titanium nitride in the upper layer as described above. Among them, in particular, aluminum is the material having good light reflecting performance and the film made of titanium nitride is the material having good light absorbing performance.

Thus, as illustrated in FIG. 5, the data lines 6a and the capacitor wiring lines 400 function as light shielding films against incident light LU that would otherwise be incident on the semiconductor layer 1a from the above in the drawing (part of the incident light LU in the drawing is incident on the capacitor wiring lines 400 and the remainder of the incident light LU transmitted through the capacitor wiring lines 400 and reaches the data lines 6a). As described above, the data lines 6a and the capacitor wiring lines 400 according to the embodiment correspond to an example of the built-in light shielding films according to the invention.

According to the exemplary embodiment, planarizing, such as chemical mechanical polishing (CMP) is performed on the surface of the third interlayer insulating film 43 such that the surface of the third interlayer insulating film 43 is planarized. Thus, as illustrated in FIG. 5, the surface of the capacitor wiring lines 400 formed on the third interlayer insulating film 43 is planarized such that concavo-convex portions are not generated on the surface of the capacitor wiring lines 400. According to the exemplary embodiment, furthermore, the surface of the fourth interlayer insulating film 44 as well as the surface of the third interlayer insulating film 43 is planarized. From this point of view, the surface of the pixel electrodes 9a or the surface of the alignment film 16 has little concavo-convex portions. Thus, since it is possible to smoothly rub the surface of the alignment film 16 (if remarkable concavo-convex portions exist on the surface of the alignment film 16, portions that has been sufficiently subjected to rubbing is not performed may be generated), it is possible to prevent the portions that has been sufficiently subjected to rubbing is not performed from causing alignment failure.

According to the exemplary embodiment, in particular, the following special arrangement relationship is established between the data lines 6a that are the built-in light shielding film and the storage capacitors 70 and the semiconductor layer 1a arranged below the data lines 6a. That is, in FIG. 5, the width W(6a) of the data lines 6a is smaller than the width W(70) of the storage capacitors 70 and the width W(1a) of the semiconductor layer 1a. The data lines 6a are formed on the second interlayer insulating film 42 not beyond the stepped portions 42DR and 42DL caused by the height of the storage capacitors 70 but on a plane that maintains uniform height. Thus, as illustrated in FIG. 5, the data lines 6a do not have any stepped portion.

On the other hand, in FIG. 6 that is a comparative example, since the width W(1a) of the semiconductor layer 1a and the width W(70) of the storage capacitors 70 are smaller than the width W(6a) of the data lines 6a, concavo-convex portions are formed on the surface of the data lines 6a due to the height of the semiconductor layer 1a and the height of the storage capacitors 70. Thus, in FIG. 6, incident light LTE or LTF is reflected by the surface of the data lines 6a in an unexpected direction such that the incident light may be incident on the channel regions of the TFTs 30. In particular, as illustrated in FIG. 6, when the end 6aP of the data line 6a is low and the center 6aC of the data line 6a is high, the light reflected by the end 6aP or an end 6aT between the end 6aP and the center 6aC is likely to be incident on the channel regions of the TFTs 30. This is because, according to the exemplary embodiment, the TFTs 30 are arranged on the TFT array substrate 10 in a matrix in plan view and the data lines 6a are arranged in stripes to define aperture regions as illustrated in FIGS. 2 and 3, so that, when light is reflected by the ends 6aP and 6aT of the data lines 6a, the light may not be incident on the semiconductor layer 1a positioned immediately under the ends 6aP and 6aT and the channel regions 1a′ (refer to FIG. 4) included in the semiconductor layer 1a, however, the light is likely to be incident on the TFTs 30 adjacent to the TFTs 30 positioned immediately under the semiconductor layer 1a (for example, refer to the reference numeral LT in the drawing). The light is more likely to be incident on the TFTs 30 adjacent to the TFTs 30 positioned immediately under the semiconductor layer 1a when the end 6aT is inclined as illustrated in FIG. 6.

However, according to the exemplary embodiment, as mentioned above, since concavo-convex portions are not generated on the surface of the data lines 6a, it is possible to prevent light from being incident on the TFTs 30 adjacent to the TFTs 30 positioned immediately under the semiconductor layer 1a. As illustrated in FIG. 5, since the light LU incident on the data lines 6a travels as reflecting light LU′, the incident light LU is not likely to be incident on the semiconductor layer 1a. Thus, according to the exemplary embodiment, since it is possible to prevent light leakage current from being generated in the TFTs 30, it is possible to display high quality images without flicker.

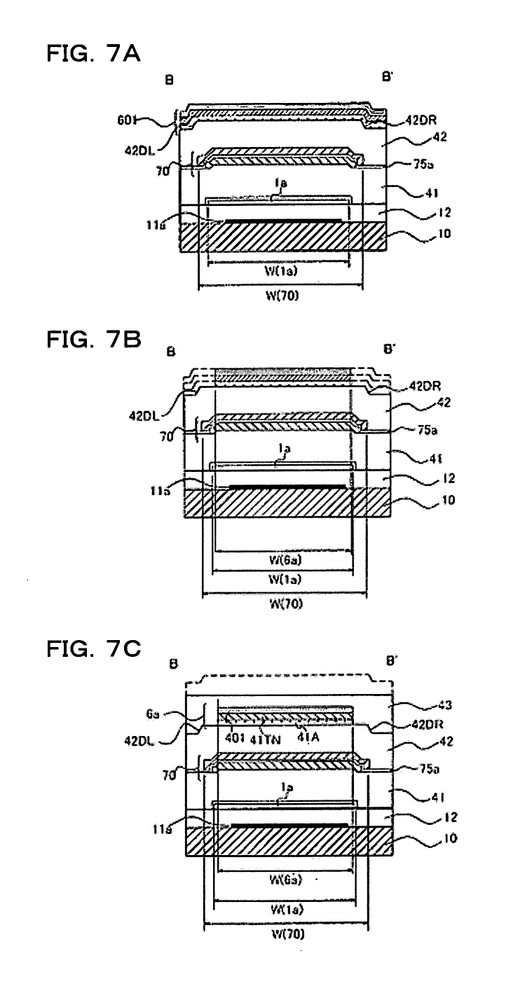

The data lines 6a as described above are manufactured as illustrated in FIG. 7. That is, in a structure where the components below the second interlayer insulating film 42 are formed on the TFT array substrate 10, as illustrated in FIG. 7(a), a data line precursor film 601 is formed on the second interlayer insulating film 42. The data line precursor film 601 is formed by a proper method selected from film formation methods, such as a sputtering method and a chemical vapor deposition (CVD) method in accordance with a material for forming the data line precursor film 601 (thus, in FIG. 7, the respective layers may be formed by different film formation methods). As illustrated in FIG. 7(a), the data line precursor film 601 is formed to cover the entire surface of the second interlayer insulating film 42 regardless of the stepped portions 42DR and 42DL. Next, as illustrated in FIG. 7(b), the data line precursor film 601 is patterned (using photolithography and etching) to leave the data line precursor film 601 formed immediately on the storage capacitors 70 and the semiconductor layer 1a in the second interlayer insulating film 42. Thus, the data line precursor film 601 on the stepped portions 42DR and 42DL is removed to form the data line 6a illustrated in FIG. 5.

Hereinafter, as illustrated in FIG. 7(c), the third interlayer insulating film 43 is formed on thus formed data line 6a and the surface of the third interlayer insulating film 43 is planarized, so the surface of the third interlayer insulating film 43 (refer to the dashed line in FIG. 7(c)) is planarized. Subsequently, the capacitor wiring lines 400, the fourth interlayer insulating film 44, the pixel electrodes 9a, and the alignment film 16 (not shown) are formed. As a result, the structure illustrated in FIG. 5 can be manufactured.

Next, FIGS. 8 and 9 will be described. In FIGS. 8 and 9, as in FIG. 5, the structure of the corresponding section is the same as the above-described structure of FIG. 4. However, in these sectional views, unlike in FIG. 5, the data lines 6a do not exist, and the capacitor wiring line relay layer 6a1 and the second relay electrodes 6a2 made of the same film as the data lines 6a are shown. Since the capacitor wiring line relay layer 6a1 and the second relay electrode 6a2 are made of the same film as the data lines 6a as described above and have the three-layered structure similar to data lines 6a as illustrated in FIG. 4, the capacitor wiring line relay layer 6a1 and the second relay electrode 6a2 function as the light shielding films and correspond to an example of the built-in light shielding films according to the invention.

According to the exemplary embodiment, in particular, the following special arrangement relationship is established between the capacitor wiring line relay layer 6a1 and the second relay electrode 6a2 that are the built-in light shielding films, and the storage capacitors 70 and the relay electrodes 719 that are arranged below the capacitor wiring line relay layer 6a1 and the second relay electrode 6a2. That is, in FIG. 8, the width V(6a1) of the capacitor wiring line relay layer 6a1 is smaller than the width V(70) (orthogonal to the width W(70)) of the storage capacitor 70. The capacitor wiring line relay layer 6a1 is formed on the second interlayer insulating film 42 not over the stepped portions 42SR and 42SL caused by the height of the storage capacitors 70 but on a plane that maintains uniform height. Thus, the capacitor wiring line relay layer 6a1 does not have any stepped portion as illustrated in FIG. 8.

On the other hand, in FIG. 9, since the relay electrode 719 and the storage capacitor 70 are formed below the second relay electrode 6a2, stepped portions caused by the heights of the relay electrodes 719 and the storage capacitor 70 are formed on the second relay electrode 6a2. On the right side of the drawing, stepped portions 41TR and 41TL caused by the height of the relay electrode 719 are formed on the first interlayer insulating film 41. On the left side of the drawing, stepped portion 42TL caused by the height of the storage capacitor 70 is formed on the second interlayer insulating film 42. The stepped portion 42TR on the right side of the drawing of the second interlayer insulating film 42 is formed by the stepped portion 41TR that affects the second interlayer insulating film 42.

Since the right end of the storage capacitor 70 and the left end of relay electrode 719 overlap each other in FIG. 9 (refer to the plan views of FIGS. 2 and 3), the stepped portion 41TL caused by the height of the relay electrode 719 affects the storage capacitor 70 such that any stepped portion is formed on the surface of the storage capacitor 70.

The second relay electrode 6a2 in FIG. 9 is formed on the second interlayer insulating film 42 not over the stepped portions 42TR and 42TL, but on a plane (excluding the portion of a convex portion 6aPR) that maintains uniform height. Thus, as illustrated in FIG. 9, the second relay electrode 6a2 has few stepped portions and, in particular, has no stepped portion at the edge thereof. Since the data line 6a is affected by the stepped portion 41TL and the height of the storage capacitor 70, the convex portion 6aPR is formed on the surface of the second relay electrode 6a2 around the center in the drawing.

As described above, since the concavo-convex portions are not generated in the capacitor wiring line relay layer 6a1 and the second relay electrode 6a2 illustrated in FIGS. 8 and 9, similar to the data line 6a described with reference to FIG. 5, even if light is incident on the capacitor wiring line relay layer 6a1 and the second relay electrode 6a2, the reflected light is not likely to be incident on the TFTs 30 adjacent to the capacitor wiring line relay layer 6a1 and the second relay electrode 6a2. Since the convex portion 6aPR is formed in the second relay electrode 6a2 around the center in the drawing as illustrated in FIG. 9, the convex portion 6aPR is not likely to induce the reflected light in an unexpected direction, in particular, to the semiconductor layer 1a of the adjacent TFT 30 (not shown) (Refer to the reference numerals LPR and LPR′ of FIG. 9.

As illustrated in FIG. 9, even if incident light LPR is reflected, since the incident light LPR is more likely to be reflected by the surface of the second relay electrode 6a2 at the position remote from the reflecting point, the reflected light LPR′ is not likely to be induced to the semiconductor layer 1a). That is, according to the invention, as illustrated in FIG. 9, any convex portion may be formed around the center of the built-in light shielding film. Even if such a convex portion is formed, light is not likely to be incident on the semiconductor layer 1a. Thus, in the built-in light shielding film according to the invention, the built-in light shielding film is preferably formed such that any stepped portion is not formed on the surface of the built-in light shielding film around the edge thereof.

Furthermore, according to the exemplary embodiment, the capacitor wiring line relay layer 6a1 and the second relay electrode 6a2 as described above are simultaneously formed when the data line precursor film 601 is patterned as illustrated in FIG. 7(b). Thus, when the data line precursor film 601 is patterned, patterning the capacitor wiring line relay layer 6a1 from above the stepped portions 42SR and 42SL so as to exclude the data line precursor film 601 and patterning the second relay electrode 6a2 from above the stepped portions 42TR and 42TL so as to exclude the data line precursor film 601 are simultaneously performed.

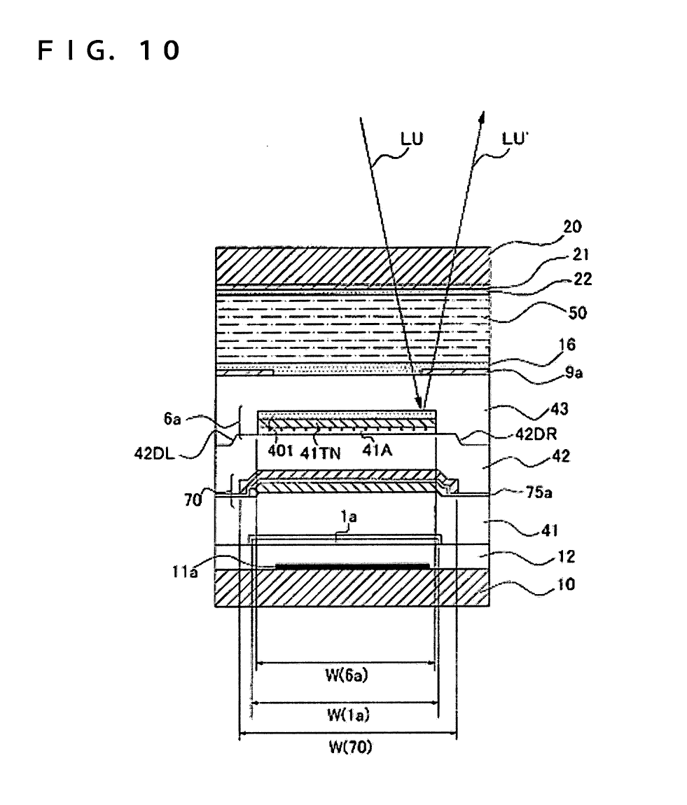

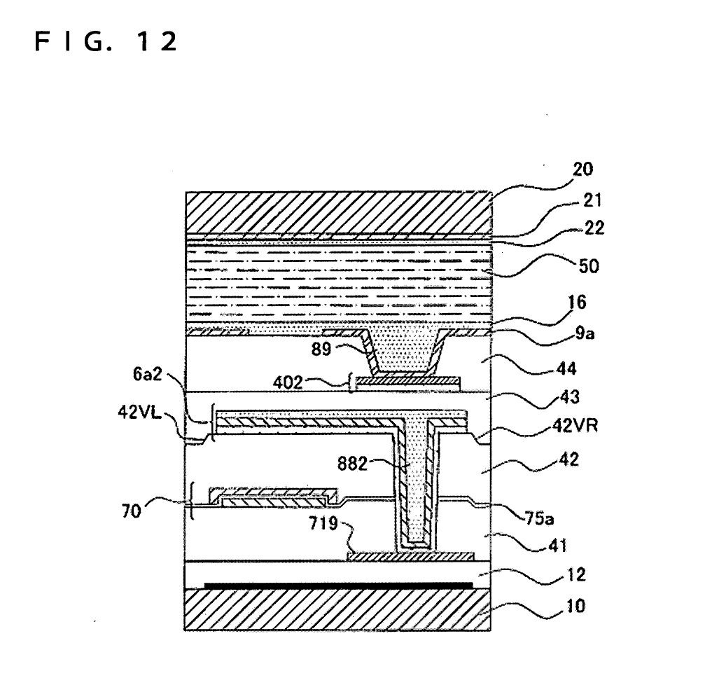

It should be understood that the invention is not limited to the forms illustrated in FIGS. 5, 8, and 9. For example, the invention may be applied to the structure of the sections illustrated in FIGS. 10 and 12, which will be described later. In the drawings referred to hereinafter, the components the same as the components denoted by the reference numerals used in FIGS. 5, 8, and 9 are denoted by the same reference numerals.

FIG. 10 is a sectional view similar to FIG. 5, which illustrates a structure in which the capacitor wiring line 400 and the fourth interlayer insulating film 44 of FIG. 5 do not exist. In such a structure, since the fourth interlayer insulating film 44 and the capacitor wiring line 400 formed on the fourth interlayer insulating film 44 do not exist unlike in FIG. 5, basically, only the data line 6a functions as the built-in light shielding film. Thus, in such a case, as noted from a structure obtained by assuming that the capacitor wiring line 400 and the fourth interlayer insulating film 44 do not exist in FIG. 6, since all of incident light LTE in the same drawing is incident on the data line 6a without being reflected by or absorbed into the capacitor wiring line 400, the above-described inconvenience becomes more severe. However, since the storage capacitor 70 wider than the data line 6a exists below the data line 6a in FIG. 10 as in FIG. 5, the concavo-convex portions are not formed on the surface of the data line 6a such that the light reflected from the data line 6a is not likely to travel in an unexpected direction and to be incident on the semiconductor layer 1a. Thus, the same effect is obtained in FIG. 10. In FIG. 10, in particular, since the capacitor wiring line 400 does not exist, it is expected to the light shielding performance of the data line 6a that is the built-in light shielding film is certainly performed. Thus, depending on the viewpoint, it is possible to obtain better effect than in FIG. 5 by the data line 6a having the above-described structure.

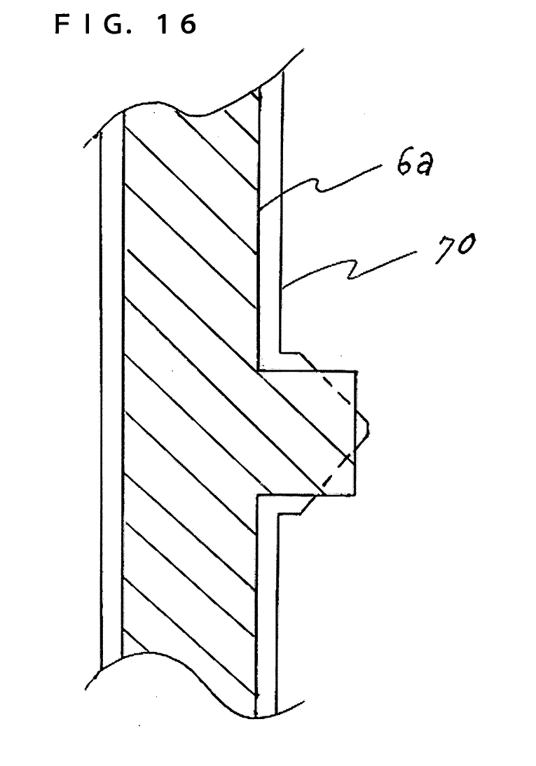

FIG. 16 illustrates an example of the planar arrangement of the built-in light shielding film 6a and the storage capacitor 70 of FIG. 10. As illustrate in FIG. 16, even when the storage capacitor 70 is not formed to include all of the built-in light shielding film 6a in plan view but to include at least a part of the built-in light shielding film 6a in plan view, it is possible to improve the light shielding performance of the built-in light shielding film 6a with respect to the semiconductor layer, which prevent the generation of light leakage current.

The built-in light shielding film is a light shielding film arranged on the TFT array substrate 10, which may be simply referred to as a light shielding film. Furthermore, the circuit elements and the wiring lines arranged below the built-in light shielding film according to the invention are not limited to the above-described circuit elements and wiring lines and any patterned conductive layer may be used.

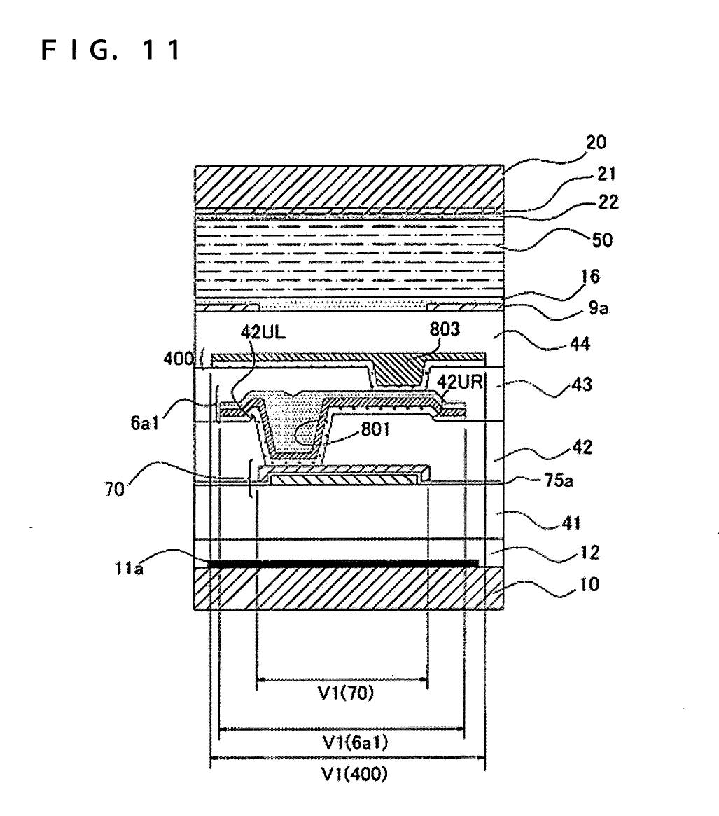

FIG. 11 is a sectional view similar to FIG. 8, which illustrates a structure in which the storage capacitor 70 of FIG. 8 is formed in a different way. In such a structure, the width V1(70) of the storage capacitor 70 is smaller than the width V(70) of the storage capacitor 70 in FIG. 8, unlike in FIG. 8. Thus, the width between stepped portions 42UR and 42UL in FIG. 11 is smaller than the width between the stepped portions 42SR and 42SL in FIG. 8. As a result, stepped portions are formed on the surface of the capacitor wiring line relay layer 6a1. Also, in such a structure, the width V1(400) of the capacitor wiring line 400 is larger than the width of the capacitor wiring line 400 in FIG. 8. More specifically, the width V1(400) of the capacitor wiring line 400 is larger than the width V1(6a1) of the capacitor wiring line relay layer 6a1.

When such a relationship is established among the capacitor wiring line 400, the capacitor wiring line relay layer 6a1, and the storage capacitor 70, it is not necessary to planarize the capacitor wiring line relay layer 6a1 unlike the capacitor wiring line relay layer 6a1 illustrated in FIG. 8. This is because the capacitor wiring line 400 positioned above the capacitor wiring line relay layer 6a1 blocks the traveling of a large amount of the light incident from the above. Furthermore, the capacitor wiring line 400 is flat since the capacitor wiring line 400 is formed on the third interlayer insulating film 43 planarized by the CMP as described above such that the light reflected by the capacitor wiring line 400 is not likely to travel in an unexpected direction. Thus, the capacitor wiring line relay layer 6a1 illustrated in FIG. 11 may have the stepped portions as illustrated in the same drawing. It is possible to adopt the structure of FIG. 11 instead of the structure of FIG. 8. However, it is difficult to adopt the structure of FIG. 11 instead of the structure of FIG. 9. This is because only half of the third relay electrode 402 on the right side in the drawing exists in FIG. 9, which makes it difficult to expect sufficient light shielding effect as described above.

As described above, when the portion (in FIG. 11) in which the planarized circuit element, such as the capacitor wiring line 400, is formed to cover the capacitor wiring line relay layer 6a1 that is the built-in light shielding film and the portion (in FIG. 9) in which the planarized circuit element, such as the capacitor wiring line 400, is formed not to cover the capacitor wiring line relay layer 6a1 that is the built-in light shielding film exist, and when the capacitor wiring line relay layer 6a1 is planarized only in the latter portion, it is possible to obtain the effect according to the exemplary embodiment and to perform freer layout in the portion (in FIG. 11) where it is not necessary to planarize the capacitor wiring line relay layer 6a1, which makes it possible to increase the degree of freedom of design.

FIG. 12 is a sectional view similar to FIG. 9, which illustrates a structure in which the storage capacitor 70 and the relay electrode 719 of FIG. 9 are formed in a different way. In such a structure, the right end of the storage capacitor 70 and the left end of the relay electrode 719 do not overlap each other unlike in FIG. 9. Thus, in FIG. 12, since the stepped portion caused by the height of the relay electrode 719 does not affect the storage capacitor 70 (refer to stepped portions 42VR and 42VL in the drawing), the convex portion 6aPR is not formed on the surface of the second relay electrode 6a2 by the heights of the relay electrode 719 and the storage capacitor 70 unlike in FIG. 9.

Thus, in FIG. 12, it is possible to make the surface of the second relay electrode 6a2 substantially flat. Thus, since the light reflected by the surface of the second relay electrode 6a2 is not likely to travel in an unexpected direction and to be incident on the semiconductor layer 1a unlike in FIG. 9, it is possible to improve the above-described effect.

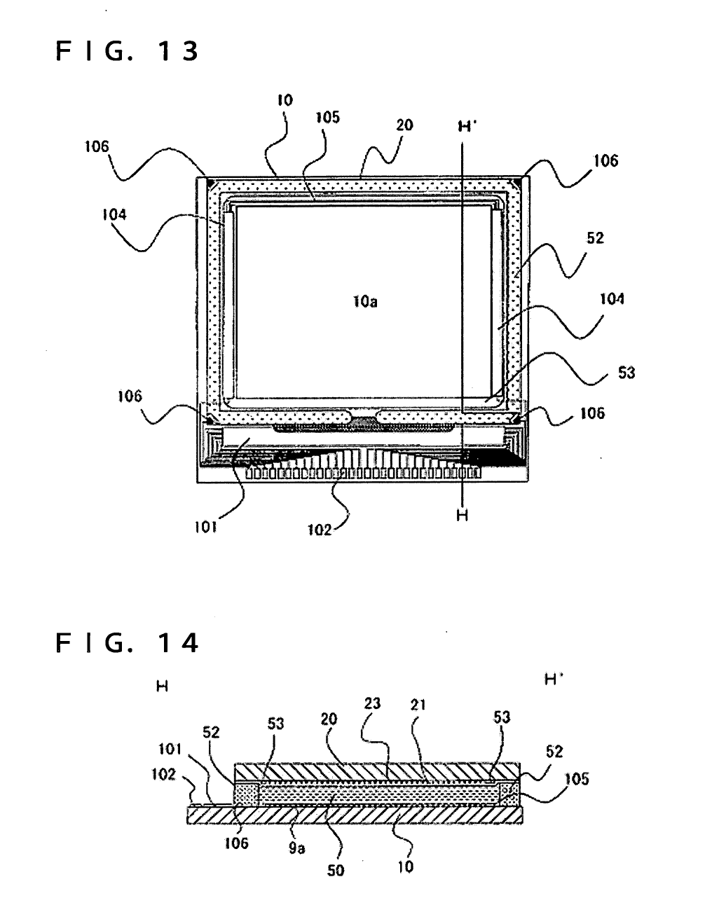

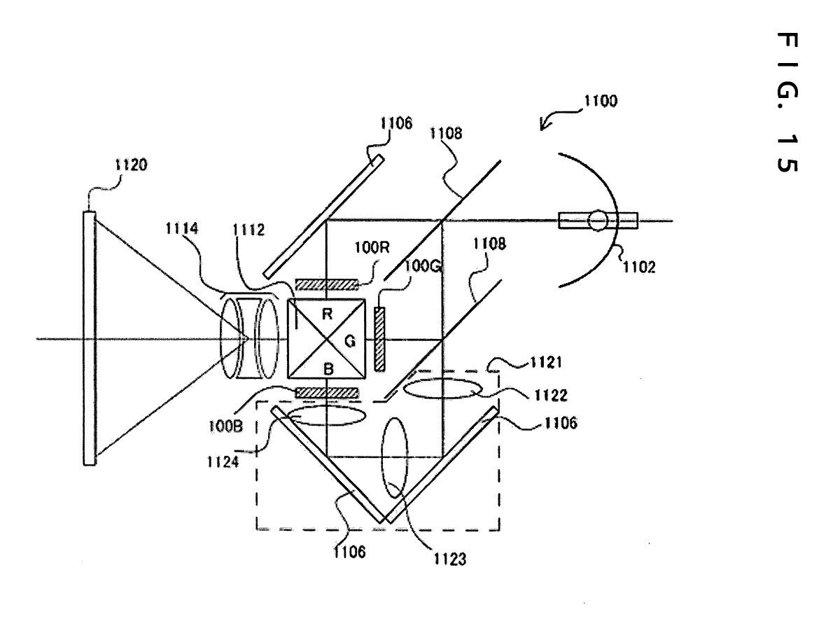

The general structure of the electro-optical device according to the exemplary embodiment will now be described with reference to FIGS. 13 and 14. FIG. 13 is a plan view of the electro-optical device in which the TFT array substrate is seen from the side of the counter substrate together with the components formed thereon. FIG. 14 is a sectional view taken along the line H-H′ of FIG. 14. A liquid crystal device with a built-in driving circuit TFT active-matrix-driving mode, which is one example of the electro-optical device, is taken as an example.

In FIGS. 13 and 14, according to the electro-optical device of the present embodiment, the TFT array substrate 10 and the counter substrate 20 face each other. The liquid crystal layer 50 is enclosed between the TFT array substrate 10 and the counter substrate 20. The TFT array substrate 10 and the counter substrate 20 are adhered to each other by the sealing material 52 provided in the sealing region around the image display region 10a.

The sealing material 52 for adhering the two substrates to each other is made of UV-curable resin or thermo-setting resin. The sealing material 52 is cured by radiating UV rays onto and heating the TFT array substrate 10, after being coated onto the TFT array substrate 10 in the manufacturing processes. Gap materials, such as glass fibers or glass beads, for making the TFT array substrate 10 and the counter substrate 20 separated from each other by a predetermined distance (a gap between the TFT array substrate 10 and the counter substrate 20) are scattered in the sealing material 52. The electro-optical device according to the invention is used for a light valve of a projector and is suitable for displaying small and enlarged images.

A frame-like light shielding film 53 that defines the frame region of the image display region 10a is provided at the side of the counter substrate 20 parallel to the inside of the sealing region where the sealing material 52 is placed. Part or all of the frame-like light shielding film 53 may be provided at the side of the TFT array substrate 10 as a built-in light shielding film. In the region of a peripheral region beyond the frame-like light shielding film 53, and outside the sealing region in which the sealing material 52 is arranged, in particular, a data line driving circuit 101 and external circuit connection terminals 102 are provided along one side of the TFT array substrate 10. Scanning line driving circuits 104 are provided along two sides adjacent to the one side and covered with the frame-like light shielding film 53. Furthermore, a plurality of wiring lines 105 are provided along the remaining one side of the TFT array substrate 10 and covered with the frame-like light shielding film 53 in order to connect the two scanning line driving circuits 104 provided on both sides of the image display region 10a.

Vertical electrical connection materials 106 that function as vertical electrical connection terminals between the two substrates are arranged at four corners of the counter substrate 20. On the other hand, the vertical electrical connection terminals are provided in the TFT array substrate 10 in the regions facing the corners. Thus, the TFT array substrate 10 and the counter substrate 20 can be electrically connected to each other.

In FIG. 14, an alignment film is formed on the TFT array substrate 10 on the pixel electrodes 9a after the wiring lines, such as the pixel switching TFTs, the scanning lines, and the data lines, are formed. On the other hand, on the counter substrate 20, other than the counter electrode 21, a light shielding film 23 in a matrix or in strips, and an alignment film on the uppermost layer are formed. The liquid crystal layer 50 is made of liquid crystal obtained by mixing one kind or various kinds of nematic liquid crystal and has a predetermined alignment state between the pair of alignment films.

On the TFT array substrate 10 illustrated in FIGS. 13 and 14, in addition to the data line driving circuit 101 and the scanning line driving circuits 104, sampling circuits for sampling image signals on image signal lines to supply the image signals to the data lines, precharge circuits for supplying a predetermined voltage level of precharge signals to the plurality of data lines prior to the image signals, and test circuits for testing the quality and defects of the electro-optical device during the manufacturing or on shipping may be formed.

Next, the general structure and, in particular, the optical structure of a projection type color display apparatus according to the exemplary embodiment, which is an example of an electronic apparatus using the above-described electro-optical device as a light valve, will be described. FIG. 15 is a schematic sectional view of the projection type color display apparatus.

In FIG. 15, a liquid crystal projector 1100, which is an example of the projection type color display apparatus according to the present embodiment, has three liquid crystal modules each including a liquid crystal device in which a driving circuit is mounted on a TFT array substrate. The liquid crystal modules are used as RGB light valves 100R, 100G, and 100B. The above-described electro-optical device (refer to FIGS. 1 to 5) is used as the light valves 100R, 100G, and 100B. In the liquid crystal projector 1100, when projection light is emitted from a lamp unit 1102 that is a white light source, such as a metal halide lamp, the emitted light is divided into light components R, G, and B corresponding to the three primary colors of RGB, by three mirrors 1106 and two dichroic mirrors 1108, and the light components R, G, and B are guided to the light valves 100R, 100G, and 100B corresponding to the respective colors. At this time, in particular, the light component B is guided via a relay lens system 1121 including an incidence lens 1122, a relay lens 1123, and an emission lens 1124 in order to reduce or prevent the optical loss from occurring due to the long light path. The light components corresponding to the three primary colors modulated by the light valves 100R, 100G, and 100B are combined by a dichroic prism 1112 and the combined light is projected onto a screen 1120 through a projector lens 1114 as a color image.

In such a projection type color display apparatus, since light emitted from the lamp unit 1102 and narrowed by the lens system 1121 is incident on the light valve 100B, a large amount of inclined light components are mixed with each other. Thus, the inclined light (for example, refer to the incident light LTF of FIG. 6) is likely to be incident on the data lines 6a, the capacitor wiring line relay layer 6a1, and the second relay electrode 6a2. Thus, the light is likely to be incident on the semiconductor layer 1a of the TFTs 30, in particular, on the channel regions 1a′ (refer to FIG. 2) such that it is likely that images with flicker be displayed on the screen 1120. That is, according to such a projection type color display apparatus, it is more likely that images with flicker be displayed on the screen 1120.

However, according to the exemplary embodiment, the electro-optical device having the above-described structure is used as the above-described light valves 100R, 100G, and 100B. Thus, since it is possible to prevent light from being incident on the semiconductor layer 1a of the TFTs 30 in the light valves 100R, 100G, and 100B, it is possible to prevent flicker from being generated on images.

It should be understood that the invention is not limited to the above-described embodiments and various changes in form and details may be appropriately made therein without departing from the spirit and idea of the invention from the reading throughout the claims and detailed description. The electro-optical device, the method of manufacturing the same, and the electronic apparatus that accompany such changes also belongs to the technical scope of the invention.

1. An electro-optical device, comprising above a substrate:
data lines extending in a fixed direction and scanning lines extending in a direction intersecting the data lines;
thin film transistors having a semiconductor layer that is disposed corresponding to the intersections of the data lines and the scanning lines;
pixel electrodes that are disposed corresponding to the thin film transistors; and
a light shielding film arranged above the semiconductor layer,
a width of the light shielding film being smaller than a width of at least one of conductive layers patterned disposed below the light shielding film.

2. An electro-optical device, comprising above a substrate:
data lines extending in a fixed direction and scanning lines extending in a direction intersecting the data lines;
thin film transistors having a semiconductor layer that are disposed corresponding to the intersections of the data lines and the scanning lines;
pixel electrodes that are disposed corresponding to the thin film transistors;
a light shielding film arranged above the semiconductor layer;
at least one conductive layer of conductive layers being patterned below the light shielding film; and
an insulating film that covers the at least one conductive layer,
the light shielding film being formed to avoid stepped portions on a surface of the insulating film, which are formed by a height of the at least one conductive layer.

3. An electro-optical device, comprising above a substrate:
data lines extending in a fixed direction and scanning lines extending in a direction intersecting the data lines;
thin film transistors having a semiconductor layer that is disposed corresponding to the intersections of the data lines and the scanning lines;
pixel electrodes that are disposed corresponding to the thin film transistors;
a light shielding film arranged above the semiconductor layer;
at least one conductive layer of conductive layers being patterned below the light shielding film; and
an insulating film that covers the at least one conductive layer and having different heights in a portion of the insulating film immediately on the at least one conductive layer and in portions of the insulating film other than a portion of the insulating film immediately on the at least one conductive layer,
the light shielding film being formed to be included in at least a part of the portion of the insulating film immediately on the at least one conductive layer in plan view.

4. The electro-optical device according to claim 1, further comprising:
a planarized insulating film, having a surface that is planarized on the light shielding film; and
at least one of a planarized circuit element and planarized wiring lines being arranged on the planarized insulating film,
in a portion where the at least one of the planarized circuit element and the planarized wiring lines is formed to cover the light shielding film and in a portion where the at least one of the planarized circuit element and the planarized wiring lines is formed not to cover the light shielding film, in at least the latter portion, a width of the light shielding film being smaller than a width of the at least one conductive layer of the patterned conductive layers.

5. The electro-optical device according to claim 1, the light shielding film functioning as the data lines.

6. The electro-optical device according to claim 1, the at least one conductive layer of the patterned conductive layers including all or a part of the thin film transistors.

7. The electro-optical device according to claim 1 further comprising storage capacitors coupled to the thin film transistors and the pixel electrodes,
the at least one conductive layer of the patterned conductive layers functioning as at least a part of the storage capacitors.

8. The electro-optical device according to claim 1 further comprising storage capacitors coupled to the thin film transistors and the pixel electrodes,
the light shielding film functioning as at least a part of the storage capacitors.

9. The electro-optical device according to claim 1,
the pixel electrodes and the thin film transistors being arranged in a matrix in a plan view of the substrate, and
the entire light shielding film being formed in a lattice shape excluding regions in which the pixel electrodes are formed.

10. The electro-optical device according to claim 1, the light shielding film having a multi-layered structure.

11. The electro-optical device according to claim 10, the multi-layered structure including a layer made of titanium nitride and a layer made of aluminum.

12. An electro-optical device, comprising above a substrate:
data lines extending in a fixed direction and scanning lines extending in a direction intersecting the data lines;
thin film transistors having a semiconductor layer that are disposed corresponding to the intersections of the data lines and the scanning lines;
pixel electrodes that are disposed corresponding to the thin film transistors;
a light shielding film arranged above the semiconductor layer;
at least one conductive layer of conductive layers patterned below the light shielding film; and
an insulating film covering the at least one conductive layer,
an edge and adjacent portion of the light shielding film being formed to avoid stepped portions on the surface of the insulating film, which are formed by a height of the at least one conductive layer.

13. A method of manufacturing an electro-optical device, comprising:
forming at least one conductive layer of patterned conductive layers above a substrate;
forming an insulating film on the at least one conductive layer;
forming a light-shielding-film precursor film on the insulating film; and
patterning the light-shielding-film precursor film so as to leave a portion of the light-shielding-film precursor film, which is formed to correspond to a portion of the insulating film immediately on the at least one conductive layer in plan view, thereby forming a light shielding film.

14. An electronic apparatus comprising the electro-optical device according to claim 1.
